(19) United States
(12) Patent Application Publication
(10) Pub. No.: US 2002/0096771 A1
(43) Pub. Date: Jul. 25, 2002

(54) Semiconductor memory device and method of fabricating the same

(75) Inventors: Yuki Yamada, Kanagawa-ken (JP); Masami Aoki, Kanagawa-ken (JP); Tohru Ozaki, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Kabushiki Kaisha Toshiba, Tokyo (JP)

(21) Appl. No.: 10/012,326

(22) Filed: Dec. 12, 2001

(30) Foreign Application Priority Data
Dec. 20, 2000 (JP) P2000-386269

(51) Int. Cl. H01L 29/40; H01L 23/52; H01L 23/48

(52) U.S. Cl. 257/758

(57) ABSTRACT

A highly reliable and highly characteristic semiconductor memory device capable of being subjected to a heat treatment process at a necessary temperature after forming a ferroelectric capacitor and wiring is provided. In Series connected TC unit ferroelectric RAM, a first contact portion of one of source/drain diffusion layers and a lower electrode and a second contact portion of an upper electrode and the other of the source/drain diffusion layers and are formed of a first oxidation resistant conductive film and a second oxidation resistant conductive film, respectively. By utilizing a memory cell block structure proper to the Series connected TC unit ferroelectric RAM, on a capacitor, provided is a hydrogen blocking film having an opening defined in a region without a memory cell, the region being present for each memory cell block.

### CROSS REFERENCE TO A RELATED APPLICATION

This application is based upon and claims benefit of priority from the prior Japanese Patent Application No. 2000-386268, filed on Dec. 20,2000; the entire contents of which are incorporated herein by reference.

### BACKGROUND OF THE INVENTION

1. Field of the Invention

The present invention relates to a semiconductor memory device having a ferroelectric capacitor, more particularly to a semiconductor memory device having a highly integrated ferroelectric memory cell array and a method of fabricating the same.

2. Description of the Related Art

The ferroelectric memory cell is developed as a highly reliable non-volatile semiconductor memory device with low power consumption. As such a ferroelectric memory cell, memory which consists of series connected memory cells each having a source terminal and a drain terminal and a ferroelectric capacitor in between said two terminals, hereinafter named “Series connected TC unit ferroelectric RAM” attracts attention because of high integration thereof.

This semiconductor memory device has a feature in that a unit formed of one transistor and one capacitor connected in parallel to each other is set as one memory cell, and that the plurality of memory cells are connected in series. Specifically, a lower electrode of the capacitor of the memory cell is connected to any one of a source region and a drain region, which are adjacent to a gate, and an upper electrode of the capacitor is connected to the other thereof, thus configuring the memory cell.

In this configuration, one block of the memory cell consists of a unit cell of 8 bit, 16 bit or the like. Each block is electrically disconnected in consideration of an increase of a bit line capacitance and an increase of an on-state resistance of a switching transistor. Typically, one block of the memory cell as described above is disconnected by a block selecting transistor. Here, a plate line for driving a capacitor must be disposed on a capacitor on an end opposite to that of a capacitor connected to a bit line in one block.

Heretofore, in order to realize this configuration, as shown in FIG. 23, source/drain diffusion layers 5 are provided on an element region 2 on a semiconductor substrate 1, and memory cell transistors 7, each consisting of a gate insulating film 3 and a gate electrode 4, are formed thereon. Above the memory cell transistors 7, formed are a conductive film 101, a lower electrode 102 on this conductive film 101, a ferroelectric film 103 on this lower electrode 102 and a pair of upper electrodes 104 on this ferroelectric film 103.

This lower electrode 102 is connected to one side of the source/drain diffusion layer 5 by a first plug electrode 100 with the conductive film 101 interposed between the lower electrode 102 and the first plug electrode 100. Moreover, the upper electrode 104 is connected to the other side of the source/drain diffusion layer 5 with a second plug electrode 105, plug wiring 106 and a third plug electrode 107 interposed therebetween together with the other upper electrode adjacent to the upper electrode 104 and not present on the same ferroelectric film 103.

The semiconductor memory device as described above is also disclosed in, for example, D. Takashima et. al., JSSCC, pp 787-792, May 1998, U.S. Pat. No. 5903492 and Japanese Patent Publication No. 2000-22010.

In the conventional semiconductor memory device as described above, the following subjects occur.

In the conventional semiconductor memory device, electrodes of the plugs and electrodes of the capacitors, which are in a direction perpendicular to a surface of the semiconductor substrate, are separately made, and these electrodes are mutually connected by the wiring in a direction parallel to the semiconductor substrate. Therefore, penetration of the plug from barrier metal owing to oxidation and the like are caused by heat treatment required for securing a capacitor characteristic of the ferroelectric film. In order to avoid the penetration and the like, a semiconductor fabrication process will have limitations on temperature and frequency of heating steps.

Moreover, in the case of using aluminum as a wiring material, it has been impossible to add thereto heat at a temperature not lower than about 400° C. as a melting point of aluminum. Therefore, after forming the wiring, it has been impossible to add a heating step at a temperature required for improving a characteristic of the ferroelectric film. Accordingly, before the wiring formation, the heat treatment has had to be carried out inevitably. In this case, it has been difficult to remove damage to the capacitor on and after the wiring formation step and to improve a memory characteristic.

Specifically, by adopting the structure as described above, the fabricating process has become complicated, and apprehension has had to be made for the penetration of the plug below the lower electrode from the barrier metal after the heating step and for a reaction between the wiring material and a barrier metal material when an uppermost wiring is formed. Moreover, limitations have been caused on the temperature used in the heating step to be performed thereafter, leading to difficulty in sufficiently recovering the ferroelectric memory from damage after a wiring or passivation step.

Hence, while it has been possible to carry out the heat treatment for improving the capacitor characteristic only at a point of time of forming the ferroelectric capacitor structure, it has been impossible to carry out further heat treatment for the improvement of the capacitor characteristic to a subsequent change of the capacitor characteristic during the wiring formation of the bit line and the like. Here, for the improvement of the capacitor characteristic, it has been necessary to add heat at a temperature of about 600° C.

Moreover, since the ferroelectric capacitor is readily deteriorated due to hydrogen, it is necessary to take measures such as deposition of an insulating film blocking hydrogen. However, in some cases, hydrogen is generated in a passivation film due to a reactive ion etching (RIE) step for the wiring and an influence of ultraviolet rays.

Meanwhile, in order to secure the characteristic of the transistor, it is necessary to perform treatment by use of hydrogen, to elevate an interface state of the transistor and to reduce a variation in threshold values of the transistor. Accordingly, there has been a problem that hydrogen does not reach a transistor unit if the capacitor is entirely covered with a hydrogen blocking film.

### SUMMARY OF THE INVENTION

A feature of the present invention is a semiconductor memory device comprising: a transistor formed on a semiconductor substrate; a first interlayer insulating film formed on the transistor; a first contact made open so as to be connected to any one of source/drain of the transistor on the semiconductor substrate in the first interlayer insulating film; a first lower electrode connected to the one of the source/drain with the first contact interposed therebetween; a ferroelectric film formed on the first lower electrode; a first upper electrode formed on the ferroelectric film; and a first connection electrode having oxidation resistant conductivity, the first connection electrode penetrating the first interlayer insulating film and connecting the first upper electrode and the other source/drain than the one connected to the first contact in the transistor.

Another feature of the present invention is a semiconductor memory device comprising: a transistor formed on a semiconductor substrate; a first interlayer insulating film deposited on the transistor; a second connection electrode having oxidation resistant conductivity, the second connection electrode being formed on the first interlayer insulating film and on a bottom and a side of a first contact made open so as to be connected to any one of source/drain of the transistor on the semiconductor substrate in the first interlayer insulating film; a first lower electrode formed on the second connection electrode having the oxidation resistant conductivity; a first ferroelectric film formed on the first lower electrode; a first upper electrode formed on the first ferroelectric film; and a first connection electrode having the oxidation resistant conductivity, the first connection electrode penetrating the first interlayer insulating film and connecting the first upper electrode and the other source/drain than the one connected to the first contact in the transistor.

Another feature of the present invention is a semiconductor memory device comprising: a transistor formed on a semiconductor substrate; a first interlayer insulating film deposited on the transistor; a first contact made open so as to be connected to any one of source/drain on the semiconductor substrate in the first interlayer insulating film; a first lower electrode connected to the one of the source/drain with the first contact interposed therebetween; a first ferroelectric film formed on the first lower electrode; first upper electrodes formed on the first ferroelectric film, the first upper electrodes being disposed to make a pair above one lower electrode; a first connection electrode having oxidation resistant conductivity, the first connection electrode penetrating the first interlayer insulating film and connecting the first upper electrode and the other source/drain than the one connected to the first contact in the transistor; and a first film having hydrogen barrier property, the first film being formed on the first connection electrode and suppressing invasion of hydrogen to layers under and below the first connection electrode.

Another feature of the present invention is a semiconductor memory device comprising: a transistor formed on a semiconductor substrate; a first interlayer insulating film deposited on the transistor; a memory cell block unit having a plurality of capacitors connected in series, each capacitor including a first lower electrode connected to any one of source/drain on the semiconductor substrate, a first ferroelectric film formed on the first lower electrode, a pair of first upper electrodes formed on the first ferroelectric film, and a first connection electrode connected to the source/drain different from the one connected to the first lower electrode; a block unit selecting transistor for selecting the memory cell block unit; a bit line connected to the block unit selecting transistor; a second interlayer insulating film covering the memory cell block unit and the above of the block unit selecting transistor; and a first hydrogen blocking film having hydrogen barrier property and an opening made open distantly by a specified distance from a boundary between the memory cell block unit and the block unit selecting transistor toward the block unit selecting transistor.

Another feature of the present invention is a method of fabricating a semiconductor memory device, comprising the steps of: forming a MOSFET on a semiconductor substrate; forming a first interlayer insulating film on the MOSFET; opening an opening in the first interlayer insulating film, the opening being made open for a first contact connected to any one of source/drain of the MOSFET on the semiconductor substrate; forming a conductive film connecting the one of the source/drain and a first lower electrode with the contact interposed therebetween; forming the first lower electrode, a first ferroelectric film and a first upper electrode upward in this order to form a ferroelectric capacitor; depositing a second interlayer insulating film entirely on the resultant structure; exposing an upper surface of the first upper electrode; opening an opening penetrating the first interlayer insulating film and the second interlayer insulating film, the opening being made open for a second contact connected to the source/drain of the MOSFET on the semiconductor substrate, the source/drain being different from the one connected to the first contact; depositing a first film having oxidation resistant conductivity on the upper surface of the first upper electrode and on a bottom and a side of the opening; processing the first film having the oxidation resistant conductivity and the first upper electrode to form a pair of capacitors; and carrying out heat treatment for the resultant structure.

Another feature of the present invention is a method of fabricating a semiconductor memory device, comprising the steps of: forming a MOSFET on a semiconductor substrate; forming a first interlayer insulating film on the MOSFET; depositing a first lower electrode on the first interlayer insulating film, the first lower electrode having a portion connected to any one of source/drain of the MOSFET on the semiconductor substrate; depositing a first ferroelectric film on the first lower electrode; depositing a pair of first upper electrodes on the first ferroelectric film; depositing a first connection electrode film connected to the other source/drain than the one connected to the first lower electrode; forming a block unit selecting transistor for selecting a memory cell block unit having a plurality of capacitors connected in series, each capacitor including the first lower electrode, ferroelectric film and upper electrodes; connecting a bit line to the block unit selecting transistor; depositing a third interlayer insulating film covering the memory cell block unit and the above of the block unit selecting transistor; depositing a first hydrogen blocking film on the third interlayer insulating film; and opening a part of the first hydrogen blocking film in a portion distant by a specified distance from a boundary between the memory cell block unit and the block unit selecting transistor toward the block unit selecting transistor.

Another feature of the present invention is a method of fabricating a semiconductor memory device, comprising the steps of: forming a MOSFET on a semiconductor substrate; forming a first interlayer insulating film on the MOSFET; forming a first hydrogen blocking film on the first interlayer insulating film; depositing a first lower electrode on the first interlayer insulating film, the first lower electrode having a portion connected to any one of source/drain of the MOSFET on the semiconductor substrate; depositing a first ferroelectric film on the first lower electrode; depositing a first upper electrodes on the first ferroelectric film; depositing a first connection electrode film connected to the other source/drain than the one connected to the first lower electrode, the first connection electrode film having oxidation resistant conductivity; forming a block unit selecting transistor for selecting a memory cell block unit having a plurality of capacitors connected in series, each capacitor including the first lower electrode, ferroelectric film and upper electrode; connecting a bit line to the block unit selecting transistor; depositing a third interlayer insulating film covering the memory cell block unit and the above of the block unit selecting transistor; defining openings in the third interlayer insulating film and the first hydrogen blocking film at a portion distant by a specified distance from a boundary between the memory cell block unit and the block unit selecting transistor toward the block unit selecting transistor; and depositing a second hydrogen blocking film on the third interlayer insulating film and the first hydrogen blocking film.

Another feature of the present invention is a method of fabricating a semiconductor memory device, comprising the steps of: forming a MOSFET on a semiconductor substrate; forming a first interlayer insulating film on the MOSFET; opening an opening in the first interlayer insulating film, the opening being made open for a contact connected to any one of source/drain of the MOSFET on the semiconductor substrate; forming a first film having oxygen resistant conductivity, a first lower electrode and a first ferroelectric film upward in this order; depositing a second interlayer insulating film entirely on the resultant structure; exposing an upper surface of the ferroelectric film; opening an opening penetrating the first interlayer insulating film and the second interlayer insulating film, the opening being made open for a contact connected to the other source/drain of the MOSFET on the semiconductor substrate; depositing a second film having the oxidation resistant conductivity on an upper surface of the first ferroelectric film and on a bottom and a side of the opening; processing the second film having the oxidation resistant conductivity to form a pair of capacitors; and carrying out heat treatment for the resultant structure.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein;

FIG. 1 is a sectional view showing a first embodiment;

FIG. 2 is a sectional view showing a step of a fabricating method of the first embodiment;

FIG. 3 is a sectional view showing a step of the fabricating method of the first embodiment;

FIG. 4 is a sectional view showing a step of the fabricating method of the first embodiment;

FIG. 5 is a sectional view showing a second embodiment;

FIG. 6 is a plan view showing the second embodiment;

FIG. 7 is a sectional view showing a third embodiment;

FIG. 8 is a sectional view showing a fourth embodiment;

FIG. 9 is a sectional view showing a fifth embodiment;

FIG. 10 is a sectional view showing a sixth embodiment;

FIG. 11 is a sectional view showing a modification example of the sixth embodiment;

FIG. 12 is a sectional view showing a seventh embodiment;

FIG. 13 is a sectional view showing a modification example of the seventh embodiment;

FIG. 14 is a sectional view showing an eighth embodiment;

FIG. 15 is a sectional view showing a ninth embodiment;

FIG. 16 is a sectional view showing a tenth embodiment;

FIG. 17 is a sectional view showing an eleventh embodiment;

FIG. 18 is a sectional view showing a twelfth embodiment;

FIG. 19 is a sectional view showing a step of a fabricating method of the twelfth embodiment;

FIG. 20 is a sectional view showing a step of the fabricating method of the twelfth embodiment;

FIG. 21 is a sectional view showing a step of the fabricating method of the twelfth embodiment;

FIG. 22 is a sectional view showing a step of the fabricating method of the twelfth embodiment; and

FIG. 23 is a sectional view showing a configuration of a conventional semiconductor memory device.

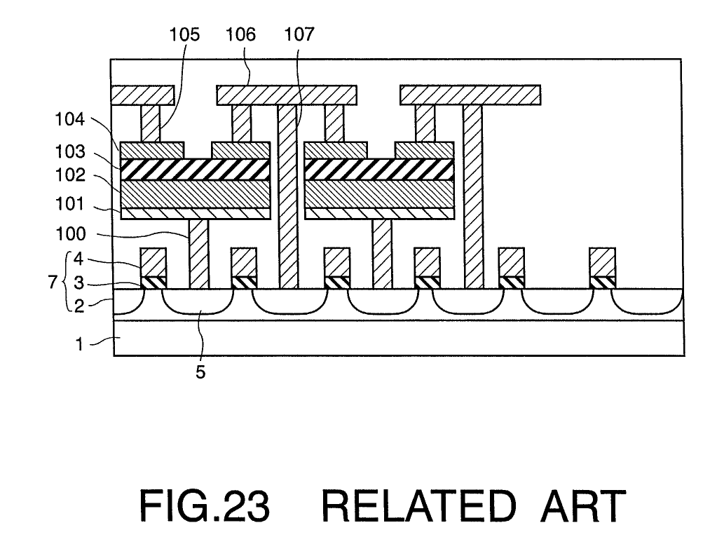

### DETAILED DESCRIPTION OF THE INVENTION

Description will be made for embodiments of the present invention with reference to the drawings. In the following description of the drawings, the same or similar numerals are added to the same or similar portions. Note that the drawings are schematic, and a relation between thicknesses and plan dimensions, a thickness ratio between the respective layers and the like are different from actual ones. Accordingly, specific thicknesses and dimensions should be determined in consideration of the following description. Moreover, also in the mutual drawings, there are portions in which the respective relations and ratios in dimension are different from one to another.

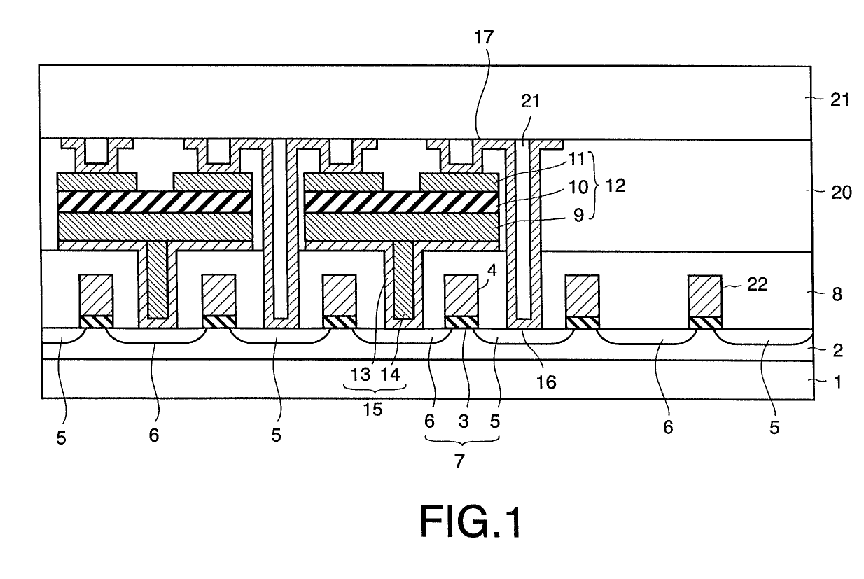

The first embodiment according to the present invention will now be described with FIGS. 1 to 4.

A configuration of this embodiment is shown in FIG. 1. A plurality of gate electrodes 4 are formed on an element region 2 on a surface of a semiconductor substrate 1 with gate insulating films 3 interposed between the gate electrodes 4 and the element region 2. In the element region 2 among the gate electrodes 4, source/drain diffusion layers 5 and 6 made of diffusion layers are formed, and thus a plurality of memory cell transistors 7 are formed.

On these memory cell transistors 7, a first interlayer insulating film 8 is formed. On this first interlayer insulating film 8, formed are a lower electrode 9 above two memory cell transistors 7 adjacent to each other, a ferroelectric film 10 on the lower electrode 9, and upper electrodes 11 formed on the ferroelectric film 10 and at positions, each corresponding to the above of each memory cell transistor 7, and thus a ferroelectric capacitor 12 is configured.

A second interlayer insulating film 20 is formed on the first interlayer insulating film 8. Furthermore, on this second interlayer insulating film 20, a third interlayer insulating film 21 is formed.

On one layer 6 of the source/drain diffusion layers 5 and 6, a first contact portion 15 between the layer 6 and the lower electrode 9 is formed of a first conductive film 13 maintaining conductivity even in an oxidation atmosphere (hereinafter referred to as oxidation resistant conductivity) and a first metal film 14 surrounded by this first conductive film 13.

Here, the first contact portion 15 is provided in the first interlayer insulating film 8 in a direction perpendicular to the surface of the semiconductor substrate 1. The first conductive film 13 is connected to the entire lower surface of the lower electrode 9.

Note that, on the source/drain diffusion layers 5 and 6, silicide films or electrodes may be formed. In this case, the first contact portion 15 is electrically connected to one of the source/drain diffusion layers 5 and 6 with the silicide film or electrode interposed therebetween.

Moreover, on the other layer 5 of the source/drain diffusion layers 5 and 6, to which the first contact portion 15 is not connected, a second contact portion 17 between the layer 5 and the upper electrode 11 is formed of a second conductive film 16 having the oxidation resistant conductivity and the third interlayer insulating film 21 having a shape surrounded by this second conductive film 16. This second contact portion 17 has a form on the upper electrode 11 in such a manner that an upper surface of the upper electrode 11 partially contacts the second contact portion 17 through an opening portion provided in the second interlayer insulating film 20.

These first and second conductive films 13 and 16 having the oxidation resistant conductivity are formed of any one of, for example, Pt, Ir and IrO₂.

Here, the ferroelectric capacitor 12 consisting of a pair of upper electrodes, one ferroelectric film and one lower electrode is disposed repeatedly in a right-and-left direction in FIG. 1 so as to correspond to the number of memory cell transistors 7 in one memory cell block. On one end of the memory cell block, provided is a block selecting transistor 22 selecting a memory cell block.

In this embodiment shown in FIG. 1, it is made possible to carry out a heating step even after the ferroelectric memory consisting of a pair of upper electrodes, one ferroelectric film and one lower electrode is formed without separately forming a plug and a wiring portion, the memory cell is formed, and the wiring is further formed. Specifically, heat treatment at about 600° C. can be carried out.

Here, in FIG. 1, a width of the lower electrode 9 in a depth direction of the drawing is, for example, about 1.2 μm. A width of the upper electrode 11 in the depth direction of the drawing is, for example, about 1.0 μm. A length of the lower electrode 9 in the right-and-left direction of FIG. 1 is, for example, about 2.2 μm. A length of the upper electrode 11 in the right-and-left direction is, for example, about 1.0 μm.

In FIG. 1, a thickness of the lower electrode 9 is, for example, from about 0.1 μm to about 0.2 μm. A thickness of the ferroelectric film 10 is, for example, from about 0.1 μm to about 0.3 μm. A thickness of the upper electrode 11 is, for example, from about 0.1 μm to about 0.2 μm. A thickness of the gate electrode 4 is about 0.2 μm. A specified size of each of the foregoing constituent components is only an example, and can be changed in accordance with a design and a specification.

Note that, for the lower electrode, a Pt film or the like laminated on a Ti film is used. A film thickness of the Pt film is set at, for example, about 100 nm. For the lower electrode, a Si layer or a metal layer may be formed under the Pt film. Moreover, Ir, IrO₂ or the like can be used as the lower electrode. Furthermore, the lower electrode can be also formed of a laminated structure of Ti layer/TiN layer/Pt layer. Yet further, SrRuO, Ru, RuO and the like can be used as the lower electrode.

Moreover, for the ferroelectric film, a composite film of SrBiTaO, a composite film of PbZrTiO (PZT, that is, Pb(Zrhd xTi₁₋ₓ)O₃) or the like is used. In the case of a PZT film, a film thickness thereof is set at, for example, about 150 nm. Moreover, a BaSrTiO-series composite film can be used. Furthermore, BaTiO₃, PLZT, LiNbO₃, K₃Li₂Nb₅O₁₅ and the like can be used as the ferroelectric film. Specifically, any case of using oxide ferroelectric having ionic bond property is effective.

Furthermore, for the upper electrode, a Pt film or the like is used. A film thickness of the Pt film is set at, for example, about 30 to 50 nm. For the upper electrode, other metal such as Al or a Si layer may be further formed on the Pt film. Moreover, Ir, IrO₂ or the like can be also used as the upper electrode. Furthermore, SrRuO, Ru, RuO and the like can be also used as the upper electrode.

For the interlayer insulating film, a BPSG film or a TEOS film can be used.

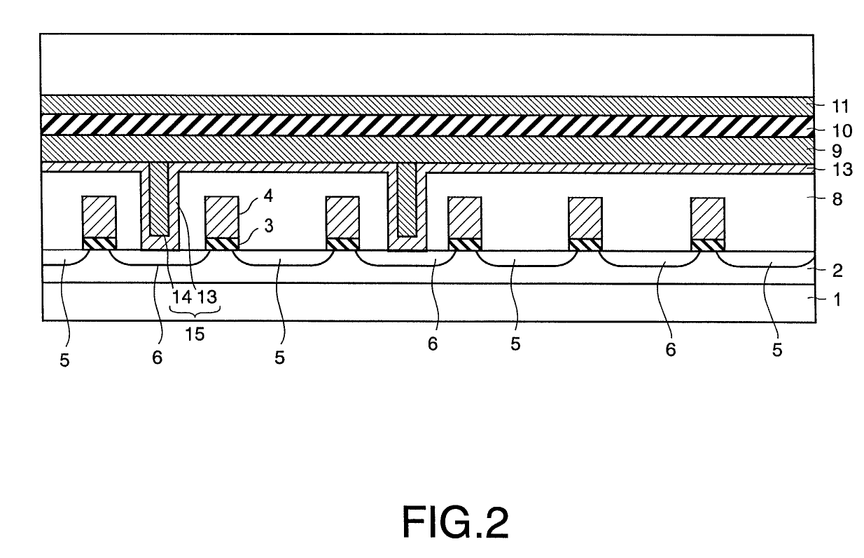

Next, description will be made for a fabricating method of this embodiment with reference to FIGS. 2 to 4.

As shown in FIG. 2, on the element region 2 on the semiconductor substrate 1, formed are the source/drain regions 5 and 6, the gate insulating films 3, and the gate electrodes 4. Thereafter, the first interlayer insulating film 8 is deposited thereon and made even, and an opening for the first contact portion 15 of the source/drain region 6 and the lower electrode 9 is defined in the first interlayer insulating film 8, then the first conductive film 13 is deposited thereon. Thereafter, the lower electrode 9, the ferroelectric film 10 and the upper electrode film 11 are sequentially deposited thereon by a CVD method or sputtering. Here, the first interlayer insulating film 8 is, for example, an interlayer insulating film of the BPSG film or the like formed by a CVD method. The surface of the first interlayer insulating film 8 is made even by a CMP method.

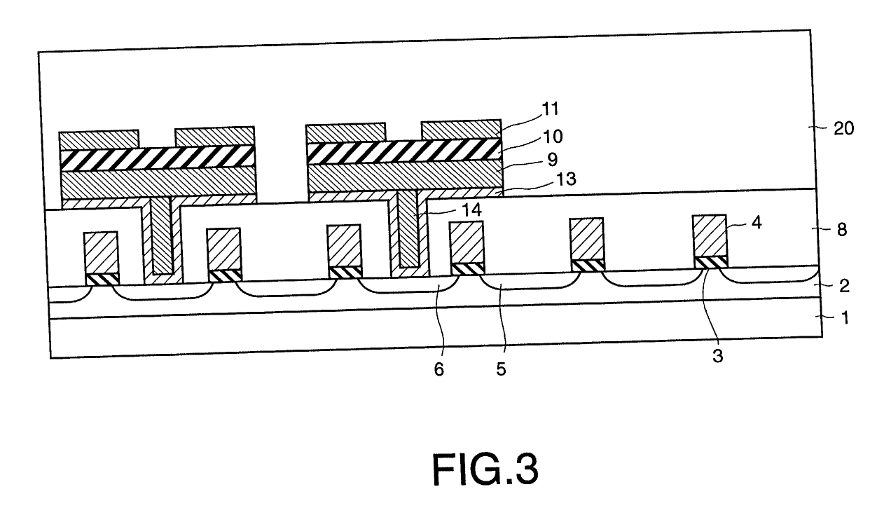

Next, as shown in FIG. 3, portions up to the upper electrode 11, the ferroelectric film 10, the lower electrode 9 and the first conductive film 13 are processed in a lump by RIE or the like to form a capacitor shape. Thereafter, the second interlayer insulating film 20 is formed thereon.

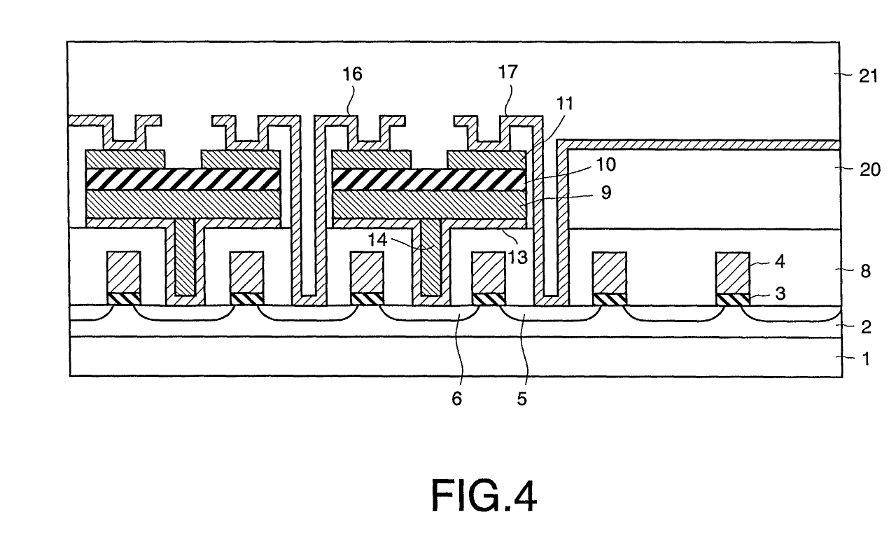

Next, as shown in FIG. 4, the second interlayer insulating film 20 is made even by the CMP method or the like. The first interlayer insulating film 8 and the second interlayer insulating film 20 are partially removed so as to expose a part of an upper portion of the upper electrode 11 and a region surface in the source/drain region 5 where the first contact portion 15 is not provided, thus defining openings for the second contact portion 15 on the upper electrode 17 and the source/drain region 5 where the first contact portion 15 is not provided. Subsequently, the second conductive film 16 is deposited on the second contact portion 17.

Next, the upper electrode 11 on the ferroelectric film 10 is separated into two together with the second conductive film 16.

Next, the third interlayer insulating film 21 is deposited on the entire surface of the resultant structure.

Next, the entire semiconductor memory device is subjected to the heating step at about 600° C. to 700° C., thus improving the capacitor characteristic of the ferroelectric.

In this embodiment, since a low melting-point material such as aluminum is not used as a wiring material to the capacitor electrode, it is possible to achieve the improvement of the characteristic of the ferroelectric film by adding heat at a high temperature of 400° C. or higher after forming the capacitor. Particularly, in order to improve a hysteresis characteristic of the ferroelectric film, heating at a temperature of 600° C. or higher is required, and in this embodiment, addition of the heat at a high temperature, which is required for the improvement of the film property, is enabled.

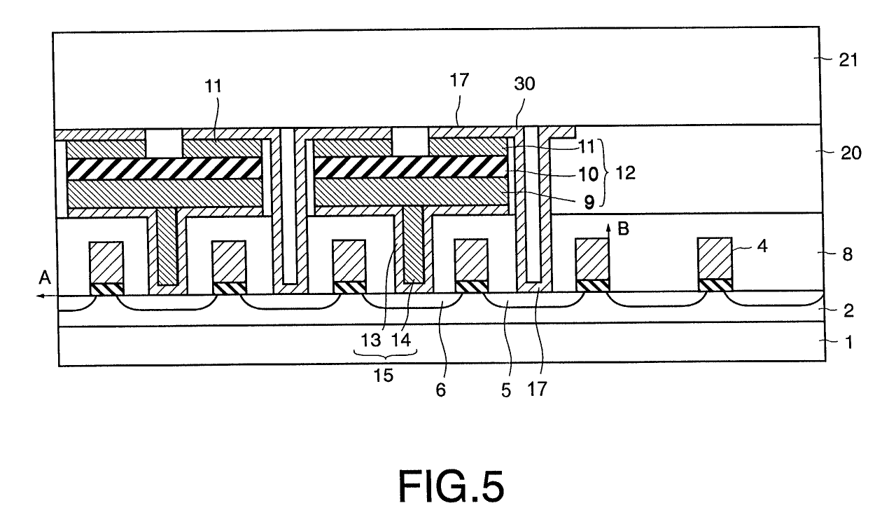

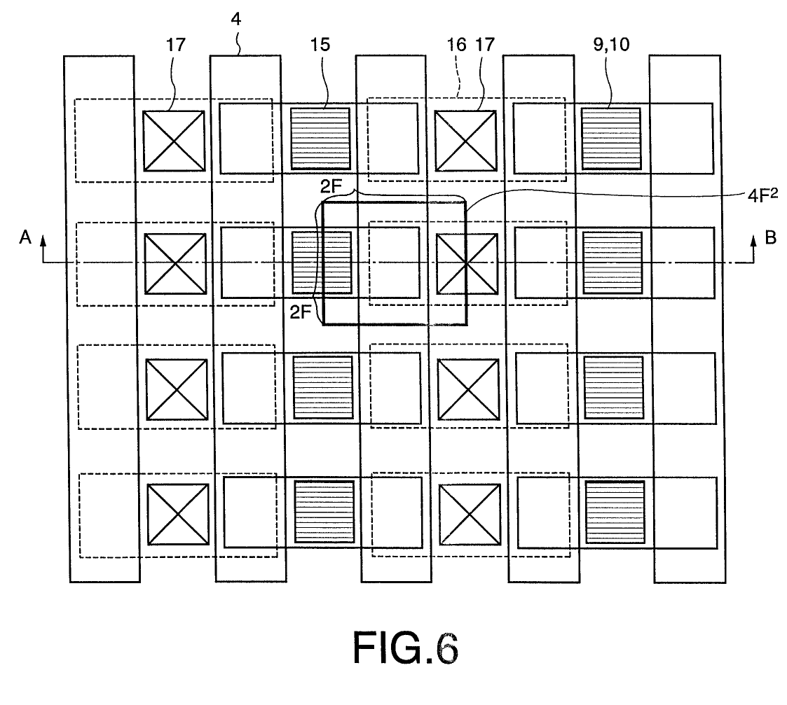

The second embodiment according to the present invention will now be described with FIGS. 5 and 6.

As shown in FIG. 5, in this embodiment, a second conductive film 30 having oxidation resistant conductivity is formed on the entire surface of the upper electrode 11, thus making it possible to reduce the number of fabricating steps. In this embodiment, the number of exposure etching steps can be reduced more than in the first embodiment.

In a fabricating method of this embodiment in accordance with the fabricating method of the first embodiment shown in FIG. 4, the surface of the deposited second interlayer insulating film 20 is made even by the CMP method or the like to expose the upper surface of the upper electrode 11 before defining the opening of the contact portion to the upper electrode 11 and the source/drain region 5, the opening serving as the second contact portion 17. Thereafter, the second conductive film 30 is deposited on the surface of the upper electrode 11, and the upper electrode 11 is separated into two.

A plan view of this embodiment is as shown in FIG. 6. A section taken on a line “A-B” in FIG. 6 corresponds to the sectional view of FIG. 5. The first contact portions 15 of the lower electrodes 9 and the source/drain regions 6, the second contact portions 17 of the upper electrodes 11 and the source/drain regions 5, the gate electrodes 4, the lower electrodes 9 and the upper electrodes 11 are located as shown in FIG. 6. Thus, 4F² of a cell size can be realized, and the number of fabricating steps is not increased. Note that, in FIG. 6, since sizes of one cell in longitudinal and lateral directions are 2F, respectively, the cell size becomes 4F² obtained by multiplying 2F by 2F.

This embodiment has an effect similar to that of the first embodiment.

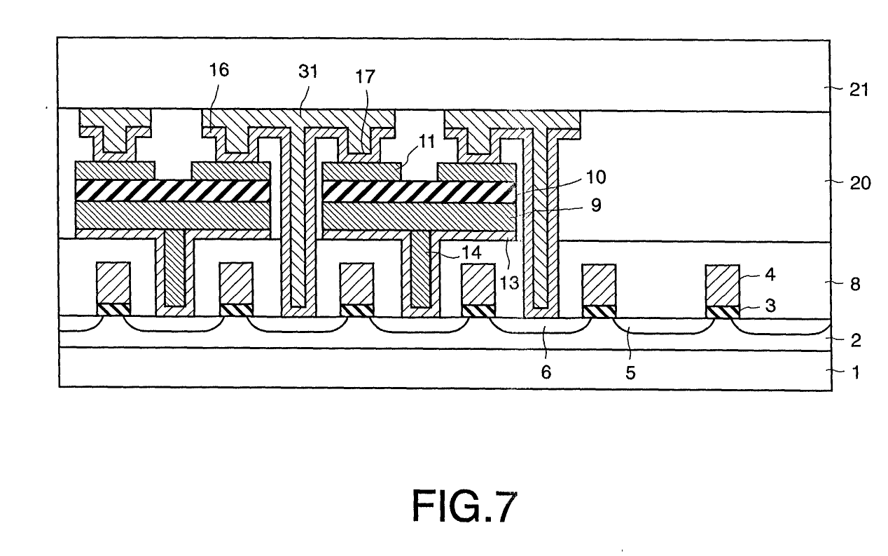

The third embodiment according to the present invention will now be described with FIG. 7.

In this embodiment, as shown in FIG. 7, a metal film 31 that does not lose conductivity even in the oxidation atmosphere is further formed on the second conductive film 16 constituted similarly to the first embodiment. In this embodiment, metal suitable for wiring can be selected as the metal film 31 while preventing the reaction between the metal film 31 and the upper electrode 11 by the second conductive film 16. Therefore, in comparison with the first embodiment, lowering in resistance of the connection wiring of the upper electrode and the source/drain can be achieved.

This embodiment has an effect similar to that of the first embodiment.

The fourth embodiment according to the present invention will now be described with FIGS. 2, 3 and 8.

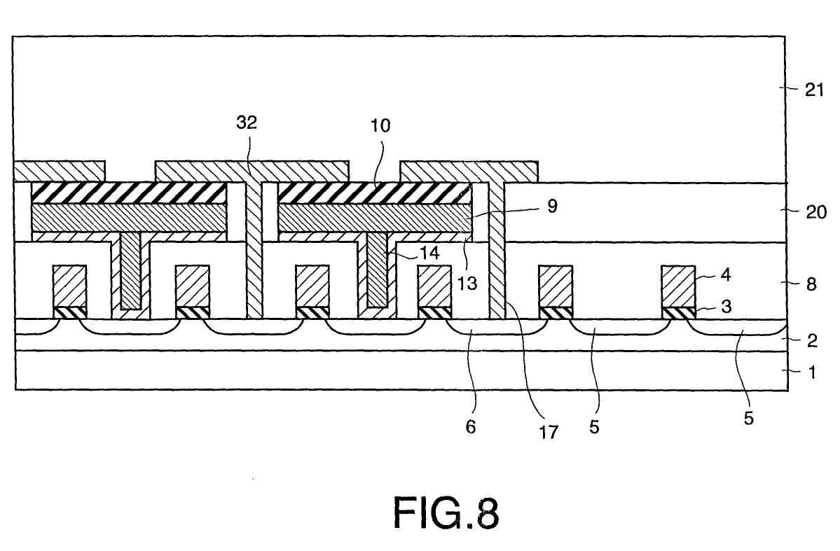

As shown in FIG. 8, in this embodiment, a second conductive film 32 having oxidation resistant conductivity is formed so as to serve also as the upper electrode 11 in the first embodiment. Since it is not necessary to use different materials for the upper electrode 11 and the second conductive film 32, the number of material types to be used can be reduced.

In a fabricating method of this embodiment in accordance with the fabricating method of the first embodiment shown in FIGS. 2 and 3, the ferroelectric film 10, the lower electrode 9 and the second conductive film 32 are formed, and the second interlayer insulating film 20 is deposited thereon. Then, an opening for the second contact 17 is defined, and the second conductive film 32 is further formed on the second conductive film 32 to increase the thickness of the second conductive film 32. Thereafter, the second conductive film 32 is separated on the ferroelectric film 10, and the third interlayer insulating film 21 is deposited on the surface thereof. The steps that follow thereafter are similar to those of the first embodiment.

This embodiment has an effect similar to that of the first embodiment.

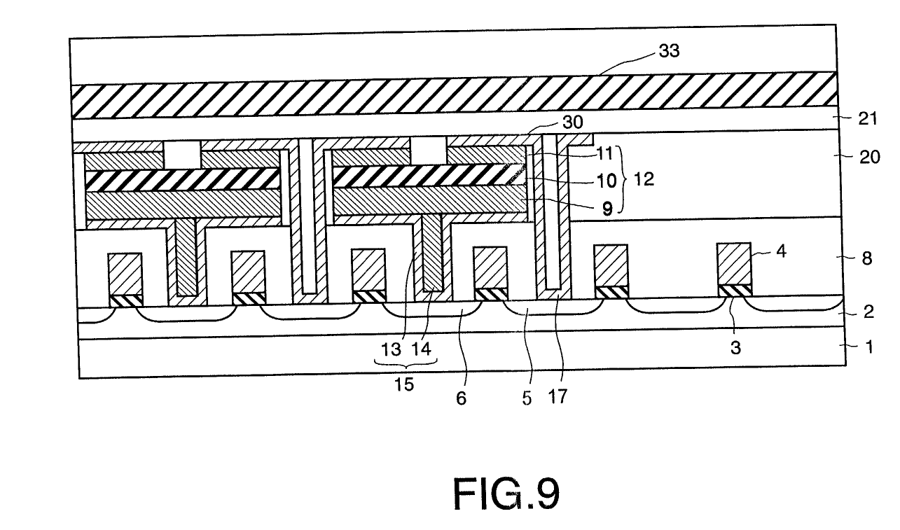

The fifth embodiment according to the present invention will now be described with FIG. 9.

As shown in FIG. 9, in this embodiment in accordance with the shape of the second embodiment, a configuration is adopted, in which a hydrogen blocking film 33 as an insulating film having hydrogen barrier property is further provided. Since the upper portion of the ferroelectric capacitor 12 is covered with the hydrogen blocking film 33, it is made possible to prevent damage to the capacitor due to invasion of hydrogen generated in the fabricating process from the above.

Here, for the insulating film having the hydrogen barrier property, alumina and the like can be used.

In a fabricating method of this embodiment, after the fabricating method of the second embodiment, the hydrogen blocking film 33 is deposited and formed.

This embodiment has effects similar to that of the first embodiment and the second embodiment.

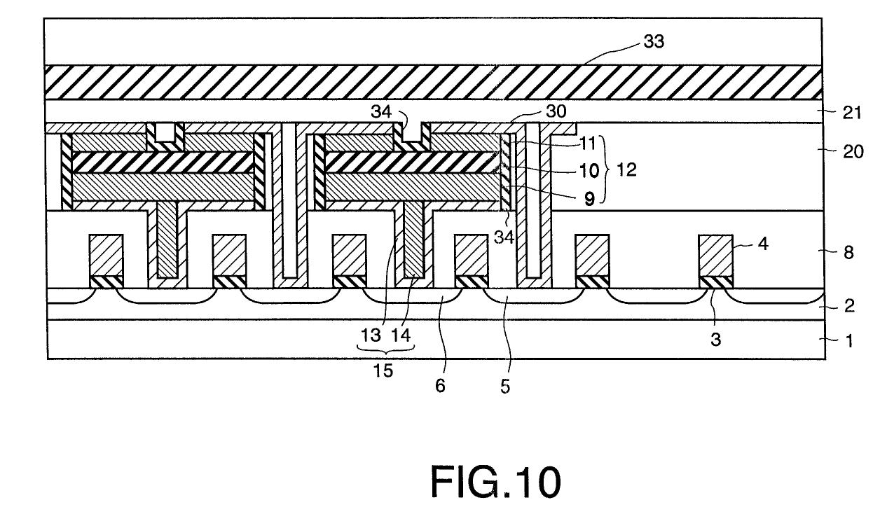

The sixth embodiment according to the present invention will now be described with FIG. 10.

As shown in FIG. 10, in addition to the configuration in the fifth embodiment, this embodiment has hydrogen blocking films 34, each serving as an insulating film having the hydrogen barrier property, on sides of the lower electrode 9, the ferroelectric film 10 and the upper electrode 11, on the surface of the ferroelectric film 10, and on edges of regions where the upper electrodes 11 and the second conductive films 30 contact each other. In this case, the hydrogen blocking film 34 may be either a single layer or plural layers. With this configuration, there is an effect of suppressing deterioration of the capacitor characteristic due to hydrogen generated in the process.

This embodiment has effects similar to that of the first embodiment and the fifth embodiment.

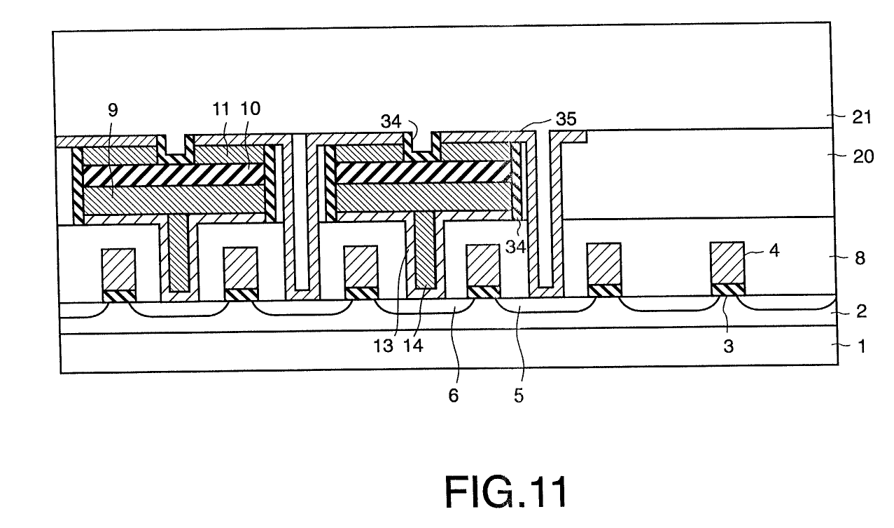

The modification example of the sixth embodiment according to the present invention will now be described with FIG. 11.

As shown in FIG. 11, in a modification example of this embodiment, the semiconductor memory device is formed in such a manner that a second conductive film 35 serving also as a hydrogen blocking film having the hydrogen barrier property is provided on the upper electrode 11 and that the hydrogen blocking film 33 in the sixth embodiment is omitted. Also in this case, damage from hydrogen in the heating step can be prevented.

This embodiment has effects similar to that of the first embodiment and the sixth embodiment.

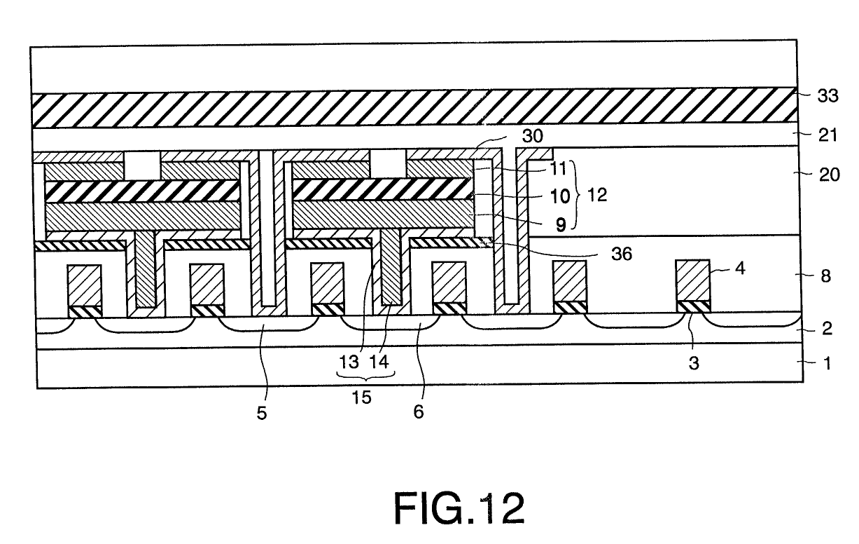

The seventh embodiment according to the present invention will now be described with FIG. 12.

As shown in FIG. 12, in this embodiment in accordance with the fifth embodiment, a hydrogen blocking film 36 as an insulating film having the hydrogen barrier property is provided under the first conductive film 13. Thus, invasion of hydrogen generated in the process from the lower portion of the capacitor can be prevented.

This embodiment has effects similar to that of the first embodiment and the fifth embodiment.

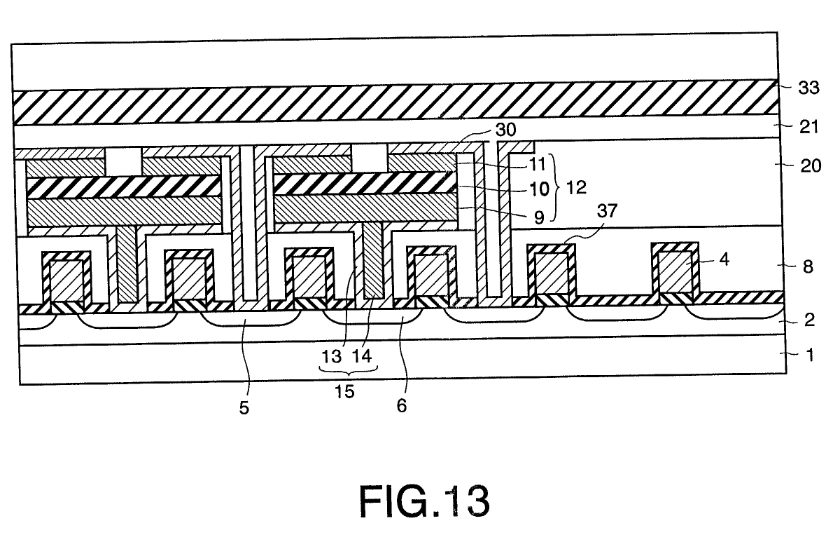

The modification example of the seventh embodiment according to the present invention will now be described with FIG. 13.

As shown in FIG. 13, instead of the hydrogen blocking film 36 in the seventh embodiment, a hydrogen blocking film 37 as an insulating film having the hydrogen barrier property is provided on peripheries of the gate electrodes 4 of the memory cell transistors and on the surface of the element region 2 on the semiconductor substrate 1. Depending on the case, the hydrogen blocking film 37 may be combined with the hydrogen blocking film 36 in the seventh embodiment. Thus, the invasion of hydrogen generated in the process from the lower portion of the capacitor can be prevented.

This modification example of the seventh embodiment has an effect similar to that of the seventh embodiment.

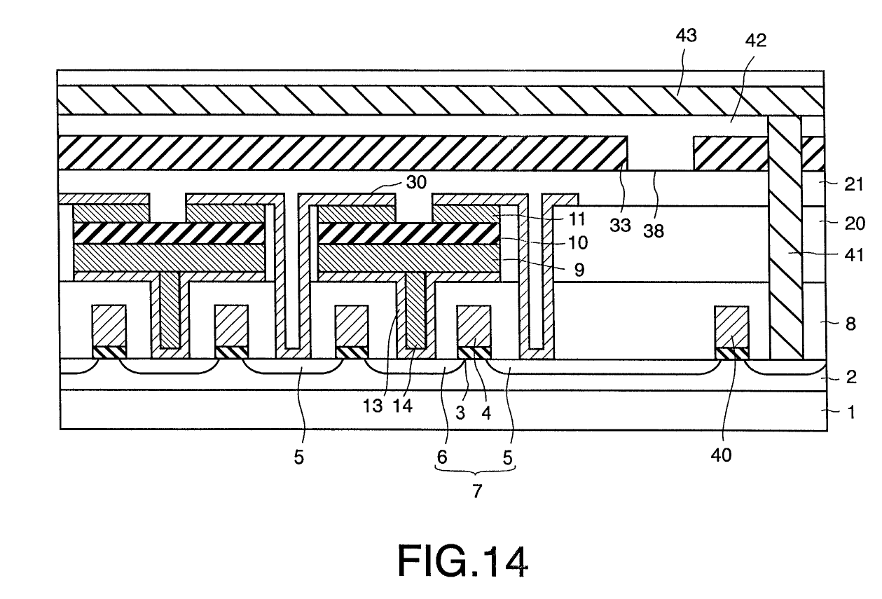

The eighth embodiment according to the present invention will now be described with FIG. 14.

As shown in FIG. 14, in this embodiment in accordance with the fifth embodiment, an opening 38 is defined in the hydrogen blocking film 33.

Here exist: a memory cell block unit in which the plurality of memory cell transistors 7 formed on the element region 2 and a plurality of capacitors are connected in series, each capacitor consisting of the lower electrode 9 connected to any one of the source/drain 5 and 6 on the element region 2 on the semiconductor substrate 1, the ferroelectric film 10 formed on the lower electrode 9, the pair of upper electrodes 11 formed on the ferroelectric film 10, and the second conductive films 30 on the upper electrodes 11; and the hydrogen blocking film 33 having the hydrogen barrier property, which covers the memory cell block unit and an upper portion of a block selecting transistor 40 selecting the memory cell block unit. An opening 38 made open distantly by a finite distance toward the block selecting transistor 40 is defined in the hydrogen blocking film 33.

By adopting this structure, while protecting the memory cell unit from the hydrogen damage by utilizing a memory cell block structure proper to the Series connected TC unit ferroelectric RAM, the characteristic improvement for the transistor unit by hydrogen annealing can be carried out.

In a fabricating method of this embodiment in accordance with the fabricating method of the fifth embodiment, after forming the hydrogen blocking film 33, the opening 38 is defined in the hydrogen blocking film 33 in the vicinity of the block selecting transistor 40, and a fourth interlayer insulating film 42 is deposited on the hydrogen blocking film 33.

Next, an opening is defined in the first interlayer insulating film 8, the second interlayer insulating film 20, the third interlayer insulating film 21 and the fourth interlayer insulating film 42, which are on and above one of the source/drain of the block selecting transistor 40.

Next, a metal layer made of metal such as an Al laminated film of Ti/TiN/Al is formed in the opening and on the fourth insulating film 42, thus a bit line contact 41 and a bit line 43 are formed.

This embodiment has an effect similar to that of the fifth embodiment.

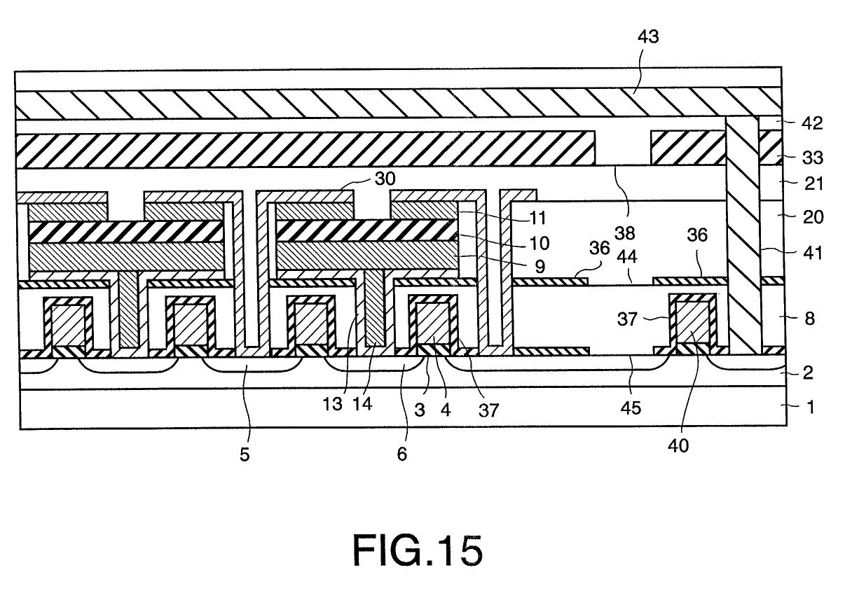

The ninth embodiment according to the present invention will now be described with FIG. 15.

As shown in FIG. 15, in this embodiment, in addition to the eighth embodiment, a hydrogen blocking film 36 is laminated between the first interlayer insulating film 8 and the second interlayer insulating film 20, and also in the hydrogen blocking film 36, an opening 44 is defined at a position coincident with the opening 38 of the hydrogen blocking film 33. Moreover, a hydrogen blocking film 37 is provided on the surfaces of the element region 2 and the gate electrodes 4, and in the hydrogen blocking film 37, an opening 45 is defined at a position coincident with the opening 38 of the hydrogen blocking film 33.

Here, by providing the multistage hydrogen blocking films, the invasion of the hydrogen to the memory cell capacitor unit can be further suppressed.

This embodiment has an effect similar to that of the eighth embodiment.

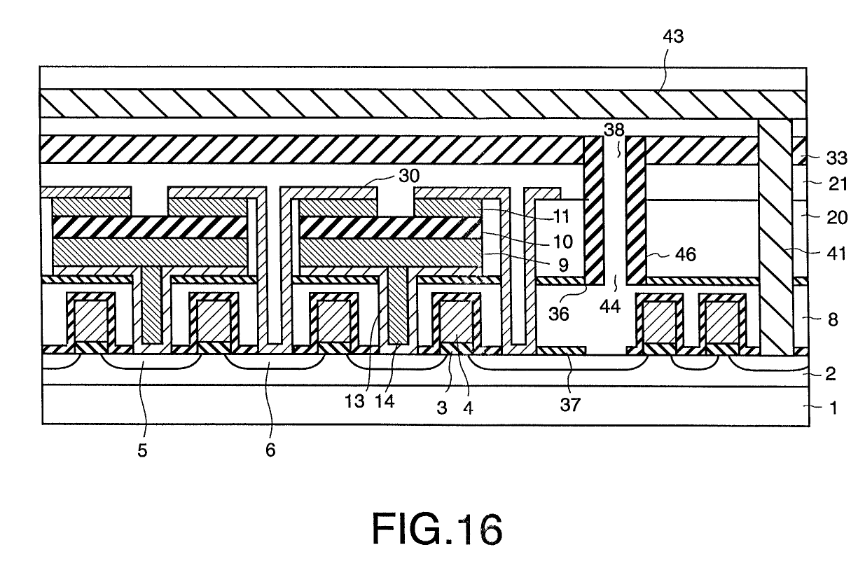

The tenth embodiment according to the present invention will now be described with FIG. 16.

As shown in FIG. 16, in this embodiment in accordance with the ninth embodiment, from a lower end of the hydrogen blocking film 33 to an upper end of the hydrogen blocking film 36, a hydrogen blocking film 46 is provided in the second interlayer insulating film 20 and the third interlayer insulating film 21, which joins the opening 38 of the hydrogen blocking film 33 and the opening 44 of the hydrogen blocking film 36. The hydrogen blocking film 46 is formed continuously in the longitudinal direction in the drawing.

With such a configuration, the invasion of hydrogen to the capacitor unit can be further suppressed.

This embodiment has an effect similar to that of the ninth embodiment.

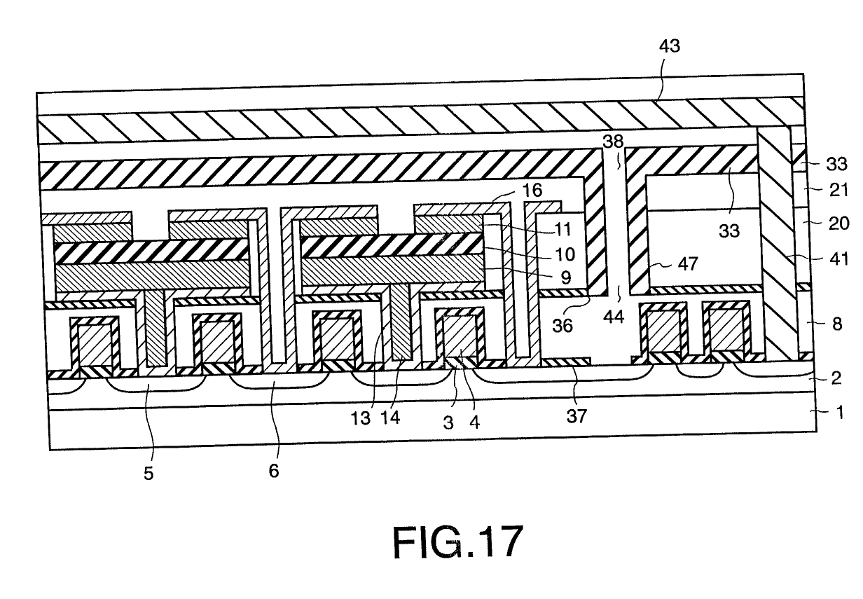

The eleventh embodiment according to the present invention will now be described with FIG. 17.

In this embodiment, instead of the hydrogen blocking film 46 in the tenth embodiment, as shown in FIG. 17, the hydrogen blocking film 33 formed in the lateral direction and a hydrogen blocking film 47 formed in the longitudinal direction are formed continuously and monolithically. In this embodiment, in a fabricating method, the step of depositing a hydrogen barrier film in the openings 38 and 44 can be performed simultaneously with the step of forming the hydrogen barrier film 33 in the lateral direction. Thus, the fabricating method is facilitated.

This embodiment has an effect similar to that of the tenth embodiment.

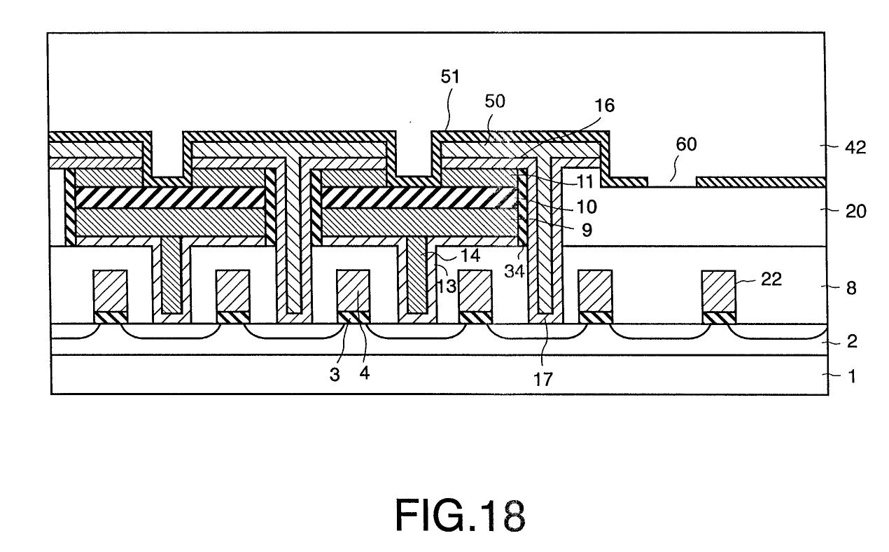

The twelfth embodiment according to the present invention will now be described with FIGS. 18 to 22.

As shown in FIG. 18, in this embodiment, in addition to the configuration in the fifth embodiment, the hydrogen blocking film 34 as an insulating film having the hydrogen barrier property is provided on the sides of the lower electrode 9, the ferroelectric film 10 and the upper electrode 11. Moreover, a metal film 50 is formed in the second contact portion 17 having the second conductive film 16 buried therein and on the second conductive film 16. Furthermore, a hydrogen blocking film 51 as an insulating film having the hydrogen barrier property is provided also on the exposed surfaces of the metal film 50 and the ferroelectric film 10 and on the edges of the regions where the upper electrodes 11 and the second conductive films 16 contact each other.

In this case, each of the hydrogen blocking films 34 and 51 may be either a single layer or plural layers. With this structure, there is an effect of suppressing deterioration of the capacitor characteristic due to hydrogen generated in the fabricating process.

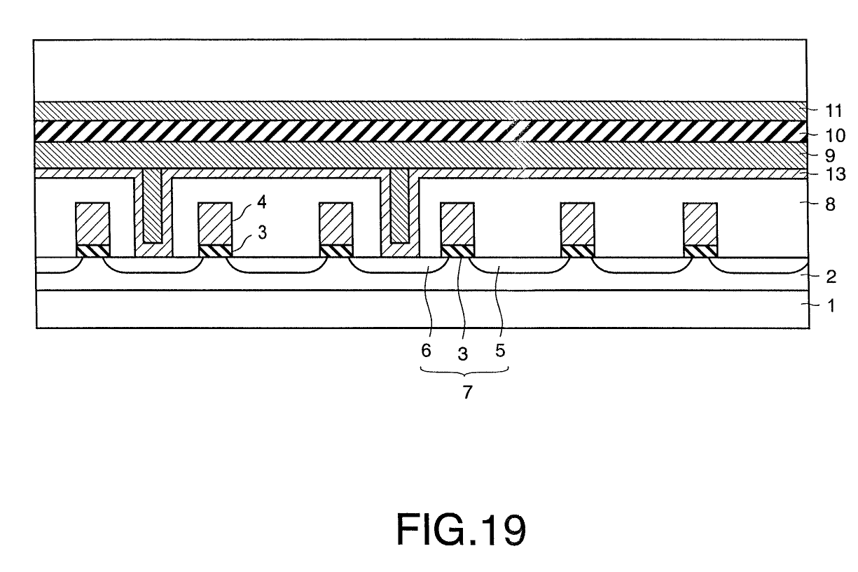

Description will be made for a method of fabricating a semiconductor memory device of this embodiment with reference to FIGS. 18 to 22. First, as shown in FIG. 19, the gate insulating films 3 are formed on the element region 2 on the semiconductor substrate 1, the gate electrodes 4, each consisting of a polysilicon/WSi laminated film, are formed thereon, and the first to fourth impurities diffusion layers 5 and 6 as source/drain are formed in the element region 2, thus forming the memory cell transistor 7.

Next, the first interlayer insulating film 8, the first conductive film 13, the lower electrode layer 9, the ferroelectric film 10 and the upper electrode layer 11 are sequentially formed. Here, as the lower electrode layer 9, conductive films made of Ti, Pt and the like are sequentially sputtered; and as the ferroelectric film 10 for the insulating film of the capacitor, a PZT film is formed; and further, as the upper electrode 11 of the capacitor, a Pt conductive film or the like is sputtered.

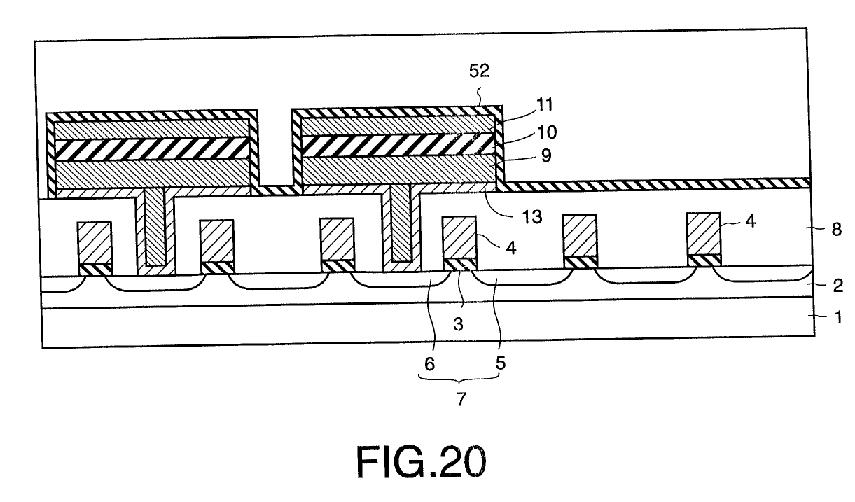

Next, as shown in FIG. 20, portions up to the upper electrode layer 11, the ferroelectric film 10, the lower electrode layer 9 and the first conductive film 13 are processed in a lump by the RIE or the like, thus forming the outer peripheral portion of the capacitor. Then, a hydrogen blocking film 52 as an insulating film having the hydrogen barrier property is deposited on the resultant structure.

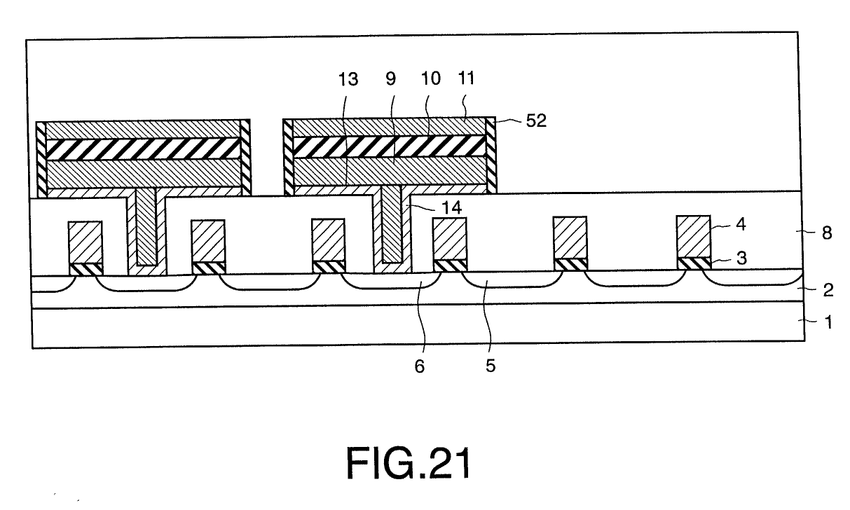

Next, as shown in FIG. 21, the upper electrode 11 is exposed.

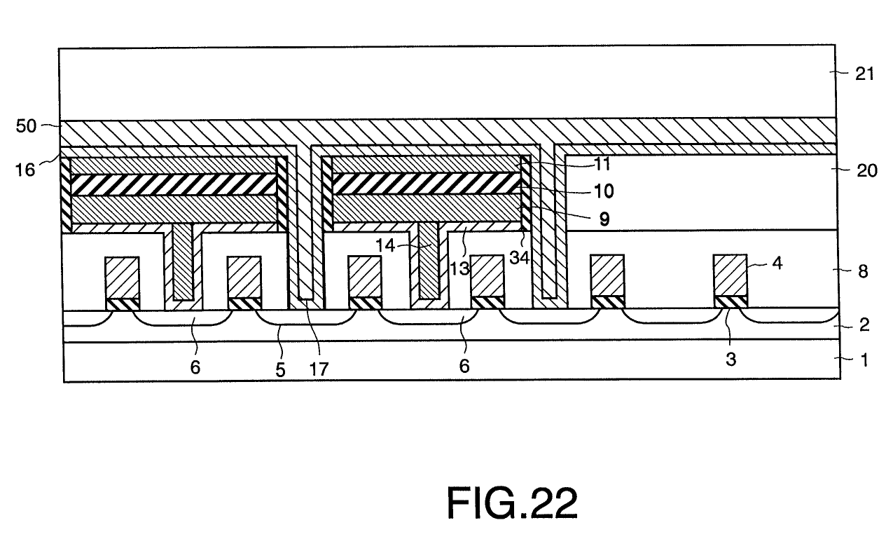

Next, as shown in FIG. 22, the second interlayer insulating layer 20 is formed by use of a plasma CVD method, and a surface thereof is made even by the CMP method. Moreover, an opening for the second contact portion 17 of the upper electrode 11 and the source/drain 5 is defined, and the second conductive film 16 is deposited on surfaces of the opening and the second interlayer insulating layer 20. Then, the metal film 50 is deposited on the entire surface of the second conductive film 16.

Next, as shown in FIG. 18, the metal film 50, the first conductive film 16 and the upper electrode 11 are processed in a lump to form a pair of the upper electrodes, and the hydrogen blocking film 51 as an insulating film having the hydrogen barrier property is deposited on the entire upper surface of the upper electrodes, and then an opening 60 is defined in the vicinity of the block selecting transistor 22. Thus, a structure capable of protecting the capacitor unit from deterioration due to hydrogen and of performing the heating step in the oxidation atmosphere is completed. The ferroelectric film is crystallized by annealing. Note that, in this embodiment, though description and illustration for a bit line contact are omitted, the bit line contact actually exists similarly to the eighth embodiment.

This embodiment has effects similar to that of the first embodiment and the fifth embodiment.

Note that the above-described embodiments can be executed in combination.

It is further understood by those skilled in the art that the foregoing description are preferred embodiments of the disclosed devices and methods and that various changes and modifications may be made in the invention without departing from the spirit and scope thereof.

According to the present invention, there can be provided a highly reliable and highly characteristic semiconductor memory device capable of being subjected to a heat treatment process at a necessary temperature after the formation of the ferroelectric capacitor, capable of avoiding the penetration of the plug material from the barrier metal and the reaction between the wiring material and the barrier metal material, and capable of eliminating the increase in the number of fabricating steps by adopting this structure. Also, a method of fabricating the semiconductor memory device can be provided.

Moreover, according to the present invention, a semiconductor memory device capable of carrying out the hydrogen treatment for the transistor while protecting the capacitor from deterioration due to hydrogen and a method of fabricating the semiconductor memory device can be provided:

What is claimed is:

1. A semiconductor memory device comprising:
a transistor formed on a semiconductor substrate;
a first interlayer insulating film formed on said transistor;
a first contact made open so as to be connected to any one of source and drain of said transistor on said semiconductor substrate in said first interlayer insulating film;
a first lower electrode connected to the one of the source and drain with said first contact interposed therebetween;
a ferroelectric film formed on said first lower electrode;
a first upper electrode formed on said ferroelectric film; and
a first connection electrode having oxidation resistant conductivity, said first connection electrode penetrating said first interlayer insulating film and connecting said first upper electrode and the other source/drain than the one connected to said first contact in said transistor.

2. A semiconductor memory device comprising:
a transistor formed on a semiconductor substrate;
a first interlayer insulating film deposited on said transistor;
a second connection electrode having oxidation resistant conductivity, said second connection electrode being formed on said first interlayer insulating film and on a bottom and a side of a first contact made open so as to be connected to any one of source and drain of said transistor on said semiconductor substrate in said first interlayer insulating film;
a first lower electrode formed on said second connection electrode having the oxidation resistant conductivity;
a first ferroelectric film formed on said first lower electrode;
a first upper electrode formed on said first ferroelectric film; and
a first connection electrode having oxidation resistant conductivity, said first connection electrode penetrating said first interlayer insulating film and connecting said first upper electrode and the other source/drain than the one connected to said first contact in said transistor.

3. The semiconductor memory device according to any one of claims 1 and 2,
wherein said first connection electrode having the oxidation resistant conductivity is formed on the entire surface of an upper portion of said first upper electrode.

4. The semiconductor memory device according to any one of claims 1 and 2, further comprising:
a third oxidation resistant conductive film laminated on said first connection electrode having the oxidation resistant conductivity.

5. The semiconductor memory device according to any one of claims 1 and 4,
wherein said first connection electrode also serves as said first upper electrode.

6. A semiconductor memory device comprising:
a transistor formed on a semiconductor substrate;
a first interlayer insulating film deposited on said transistor;
a first contact made open so as to be connected to any one of source and drain on said semiconductor substrate in said first interlayer insulating film;
a first lower electrode connected to the one of the source and drain with said first contact interposed therebetween;
a first ferroelectric film formed on said first lower electrode;
first upper electrodes formed on said first ferroelectric film, said first upper electrodes being disposed to make a pair above one lower electrode;
a first connection electrode having oxidation resistant conductivity, said first connection electrode penetrating said first interlayer insulating film and connecting said first upper electrode and the other source/drain than the one connected to said first contact in said transistor; and
a first insulating film having hydrogen barrier property, said first insulating film being formed on said first connection electrode and suppressing invasion of hydrogen to layers under and below said first connection electrode.

7. The semiconductor memory device according to claim 6, further comprising:
a single- or plural-layered second insulating film having hydrogen barrier property, said second insulating film being laminated on sides of said first lower electrode, said first ferroelectric film and said first upper electrode, on said first ferroelectric film between said first upper electrodes and on said upper electrode except a region which said first upper electrode and said first connection electrode are contacting.

8. The semiconductor memory device according to claim 7,
wherein said first connection electrode having the oxidation resistant conductivity also has hydrogen barrier property.

9. The semiconductor memory device according to any one of claims 6 and 7, further comprising:
a single- or plural-layered third insulating film having hydrogen barrier property, said third insulating film being laminated under said first lower electrode.

10. A semiconductor memory device comprising:
a transistor formed on a semiconductor substrate;
a first interlayer insulating film deposited on said transistor;
a memory cell block unit having a plurality of capacitors connected in series, each capacitor including a first lower electrode connected to any one of source and drain on said semiconductor substrate, a first ferroelectric film formed on said first lower electrode, a pair of first upper electrodes formed on said first ferroelectric film, and a first connection electrode connected to the source/drain different from the one connected to said first lower electrode;
a block unit selecting transistor for selecting said memory cell block unit;
a bit line connected to said block unit selecting transistor;
a second interlayer insulating film covering said memory cell block unit and the above of said block unit selecting transistor; and
a first hydrogen blocking film having hydrogen barrier property and an opening made open distantly by a specified distance from a boundary between said memory cell block unit and said block unit selecting transistor toward said block unit selecting transistor.

11. The semiconductor memory device according to any one of claims 1, 2, 6 and 10,
wherein said transistor, said lower electrode, said ferroelectric film, said upper electrode and said first connection electrode configure the memory cell block unit,
said semiconductor memory device further comprising:
the block unit selecting transistor for selecting said memory cell block unit;
the bit line connected to said block unit selecting transistor;
the second interlayer insulating film covering said memory cell block unit and the above of said block unit selecting transistor; and
the first hydrogen blocking film having the hydrogen barrier property and the opening made open distantly by the specified distance from the boundary between said memory cell block unit and said block unit selecting transistor toward said block unit selecting transistor.

12. The semiconductor memory device according to claim 10, further comprising:
a single- or plural-layered second hydrogen blocking film laminated between said semiconductor substrate and said lower electrode, said second hydrogen blocking film having an opening made open distantly by a specified distance from a boundary between said memory cell block unit and said block unit selecting transistor toward said block unit selecting transistor.

13. The semiconductor memory device according to claim 12,
wherein a position of the opening of said first hydrogen blocking film is coincident with a position of the opening of said second hydrogen blocking film,
said semiconductor memory device further comprising:
a third hydrogen blocking film formed continuously on a sidewall of the opening in the longitudinal direction from a lower end of said first hydrogen blocking film to an upper end of said second hydrogen blocking film.

14. The semiconductor memory device according to claim 12,
wherein said first hydrogen blocking film and said second hydrogen blocking film contact each other in the vicinity of the opening, and the hydrogen blocking film exists between the capacitor and the opening.

15. The semiconductor memory device according to claim 10,
said semiconductor memory device further comprising:
a single- or plural-layered second hydrogen blocking film laminated between said semiconductor substrate and said first lower electrode, said second hydrogen blocking film having an opening made open distantly by a specified distance from a boundary between said memory cell block unit and said block unit selecting transistor toward said block unit selecting transistor; and
a third hydrogen blocking film formed continuously on a sidewall of the opening in the longitudinal direction from a lower end of said first hydrogen blocking film to an upper end of said second hydrogen blocking film; and
wherein said first connection electrode has the oxidation resistant conductivity, and a position of the opening of said first hydrogen blocking film is coincident with a position of the opening of said second hydrogen blocking film.

16. The semiconductor memory device according to claim 10,
said semiconductor memory device further comprising:
a single- or plural-layered second hydrogen blocking film laminated between said semiconductor substrate and said first lower electrode, said second hydrogen blocking film having an opening made open distantly by a specified distance from a boundary between said memory cell block unit and said block unit selecting transistor toward said block unit selecting transistor, and
wherein said first connection electrode has the oxidation resistant conductivity, said first hydrogen blocking film and said second hydrogen blocking film contact each other in the vicinity of the opening, and said first hydrogen blocking film and said second hydrogen blocking film exist between the capacitor and the opening.

17. A method of fabricating a semiconductor memory device, comprising:
forming a MOSFET on a semiconductor substrate;
forming a first interlayer insulating film on said MOSFET;
opening an opening in said first interlayer insulating film, said opening being made open for a first contact connected to any one of source and drain of said MOSFET on said semiconductor substrate;
forming a conductive film connecting the one of the source and drain and a first lower electrode with said contact interposed therebetween;
forming said first lower electrode, a first ferroelectric film and a first upper electrode upward in this order to form a ferroelectric capacitor;
depositing a second interlayer insulating film on an entire surface of the resultant structure;
exposing an upper surface of said first upper electrode;
opening an opening penetrating said first interlayer insulating film and said second interlayer insulating film, said opening being made open for a second contact connected to the source/drain of said MOSFET on said semiconductor substrate, said source/drain being different from the one connected to said first contact;
depositing a first film having oxidation resistant conductivity on the upper surface of said first upper electrode and on a bottom and a side of said opening;
processing said first film having the oxidation resistant conductivity and said first upper electrode to form a pair of capacitors; and
carrying out heat treatment for the resultant structure.

18. The method of fabricating a semiconductor memory device according to claim 17, further comprising:
depositing a second film having oxidation resistant conductivity on said first film having the oxidation resistant conductivity; and
depositing a third interlayer insulating film on said second film having the oxidation resistant conductivity.

19. The method of fabricating a semiconductor memory device according to any one of claims 17 and 18, further comprising:
depositing a first hydrogen blocking film after said step of forming a first upper electrode; and
exposing the upper surface of said first upper electrode by removing said first hydrogen blocking film on said upper electrode.

20. The method of fabricating a semiconductor memory device according to any one of claims 17 and 18, further comprising:
depositing a second film having hydrogen barrier property on a periphery of a gate of a transistor and on said semiconductor substrate after forming the MOSFET.

21. The method of fabricating a semiconductor memory device according to any one of claims 17 and 18, further comprising:
depositing a third film having hydrogen barrier property after depositing a first interlayer insulating film; and
removing said third film having the hydrogen barrier property on a region other than a lower portion of the capacitor.

22. The method of fabricating a semiconductor memory device according to claim 19, further comprising:
depositing a single- or plural-layered fourth insulating film to be processed in a shape of a sidewall of said first lower electrode, a first ferroelectric film and a first upper electrode before depositing the first insulating film having hydrogen barrier property.

23. The method of fabricating a semiconductor memory device according to claim 17, further comprising:
depositing a second lower electrode after depositing the first lower electrode.

24. A method of fabricating a semiconductor memory device, comprising:
forming a MOSFET on a semiconductor substrate;
forming a first interlayer insulating film on said MOSFET;
depositing a first lower electrode on said first interlayer insulating film, said first lower electrode having a portion connected to any one of source and drain of said MOSFET on said semiconductor substrate;
depositing a first ferroelectric film on said first lower electrode;
depositing a pair of first upper electrodes on said first ferroelectric film;
depositing a first connection electrode film connected to the other source/drain than the one connected to said first lower electrode;
forming a block unit selecting transistor for selecting a memory cell block unit having a plurality of capacitors connected in series, each capacitor including said first lower electrode, ferroelectric film and upper electrodes;
connecting a bit line to said block unit selecting transistor;
depositing a third interlayer insulating film covering the memory cell block unit and the above of the block unit selecting transistor;
depositing a first hydrogen blocking film on said third interlayer insulating film; and
opening a part of said first hydrogen blocking film in a portion distant by a specified distance from a boundary between said memory cell block unit and said block unit selecting transistor toward said block unit selecting transistor.

25. The method of fabricating a semiconductor memory device according to claim 24, further comprising:
forming a second hydrogen blocking film under said first lower electrode after forming a MOSFET; and
defining an opening in said second hydrogen blocking film in the vicinity of the opening defined in said first hydrogen blocking film.

26. The method of fabricating a semiconductor memory device according to claim 25, further comprising:
forming a third hydrogen blocking film in the opening in said first hydrogen blocking film and the opening in said second hydrogen blocking film after defining an opening in said second hydrogen blocking film; and
leaving said third hydrogen blocking film as sidewalls of the openings in said first hydrogen blocking film and said second hydrogen blocking film.

27. The method of fabricating a semiconductor memory device according to claim 26, further comprising:
depositing said first hydrogen blocking film and said second hydrogen blocking film in the vicinities of the opening in said first hydrogen blocking film and the opening in said second hydrogen blocking film so as to form a continuous laminated structure.

28. A method of fabricating a semiconductor memory device, comprising:
forming a MOSFET on a semiconductor substrate;
forming a first interlayer insulating film on said MOSFET;
forming a first hydrogen blocking film on said first interlayer insulating film;
depositing a first lower electrode on said first interlayer insulating film, said first lower electrode having a portion connected to any one of source and drain of said MOSFET on said semiconductor substrate;
depositing a first ferroelectric film on said first lower electrode;
depositing a first upper electrode on said first ferroelectric film;
depositing a first connection electrode film connected to the other of the source/drain different from the one connected to said first lower electrode, said first connection electrode film having oxidation resistant conductivity;
forming a block unit selecting transistor for selecting a memory cell block unit having a plurality of capacitors connected in series, each capacitor including said first lower electrode, ferroelectric film and upper electrode;
connecting a bit line to said block unit selecting transistor;
depositing a third interlayer insulating film covering the memory cell block unit and the above of the block unit selecting transistor;
defining openings in said third interlayer insulating film and said first hydrogen blocking film at a portion distant by a specified distance from a boundary between said memory cell block unit and said block unit selecting transistor toward said block unit selecting transistor; and
depositing a second hydrogen blocking film on said third interlayer insulating film and said first hydrogen blocking film.

29. A method of fabricating a semiconductor memory device, comprising: forming a MOSFET on a semiconductor substrate; forming a first interlayer insulating film on said MOSFET; opening an opening in said first interlayer insulating film, said opening being made open for a contact connected to any one of source and drain of said MOSFET on said semiconductor substrate; forming a first film having oxygen resistant conductivity, a first lower electrode and a first ferroelectric film upward in this order; depositing a second interlayer insulating film on an entire surface of the resultant structure; exposing an upper surface of said ferroelectric film; opening an opening penetrating said first interlayer insulating film and said second interlayer insulating film, said opening being made open for a contact connected to the other of the source/drain of said MOSFET on said semiconductor substrate; depositing a second film having oxidation resistant conductivity on an upper surface of said first ferroelectric film and on a bottom and a side of said opening; processing said second film having the oxidation resistant conductivity to form a pair of capacitors; and carrying out heat treatment for the resultant structure.
